(19) United States
(12) Patent Application Publication
(10) Pub. No.: US 2012/0258572 A1
(43) Pub. Date: Oct. 11, 2012

(54) ADHESIVE SHEET AND PRODUCTION METHOD FOR ELECTRONIC COMPONENT

(75) Inventor: Tomomichi Takatsu, Shibukawa-shi (JP)

(73) Assignee: DENKI KAGAKU KOGYO KABUSHIKI KAISHA, Tokyo (JP)

(21) Appl. No.: 13/518,055

(22) PCT Filed: Oct. 29, 2010
(86) PCT No.: PCT/JP2010/069319

§ 371 Date: Jun. 21, 2012

(30) Foreign Application Priority Data
Dec. 21, 2009 (JP) 2009-288855

(51) Int. Cl. C09J 133/00; H01L 21/78; C09J 7/02

(52) U.S. Cl. 438/113; 428/355 CN; 257/E21.599

(57) ABSTRACT

Disclosed is an adhesive sheet that has a base film and an ultraviolet curable adhesive layered upon the base film. The ultraviolet curable adhesive includes 100 parts by mass of an acrylic ester copolymer with a weight-average molecular weight of at least one million, 20 to 200 parts by mass of a photopolymerizable acrylate having at least three carbon-carbon double bonds, and 0.1 to 10 parts by mass of an isocyanate curing agent. From among the monomers used during the copolymerization of the acrylic ester copolymer, a monomer having one or both of a hydroxyl group and a carboxyl group is included at no more than 0.1 mass %.

### TECHNICAL FIELD

The present invention relates to an adhesive sheet and a production method for electronic components using it.

### BACKGROUND ART

Electronic components are normally produced by bonding an adhesive sheet to the backside (the non-circuit pattern formed surface) of an electronic component assembly having a plurality of circuit patterns formed on a single substrate wafer or circuit board, dicing the assembly of electronic components into individual chips, picking up the individual chips, and then using an adhesive to secure the chips in a lead frame. Normally, dicing is conducted after the electronic component assembly is bonded to the adhesive sheet, and with regards to the adhesive of the adhesive sheet, the technique of using an acrylic acid ester co-polymer, which is a type of UV-curable adhesive, as the chief component has been disclosed (see Patent Documents 1 and 2). By using a UV-curable adhesive and irradiating with an ultraviolet light before pickup, the adhesive can be hardened and its adhesive force can be reduced, making the picking up stage easy to conduct.

Patent Document 1: JP-A2009-147251

Patent Document 2: JP-A2009-256458

### SUMMARY OF THE INVENTION

Due to the high integration of semiconductor parts, thinner chips are desired. Because of this, in the above-described production methods for electronic components, conducting a backgrinding step using a grinding machine to grind and thin the rear surface of the electronic component assembly before dicing the electronic component assembly has become mainstream. However, in the case where backgrinding is performed, there is the problem of a reduced success rate of chip pickup from the adhesive sheet after dicing.

After earnest consideration by the inventors, it was discovered that, due to oxygen in the atmosphere, an oxide film naturally forms on the surface of the electronic component assembly, and when that oxide film is removed by the backgrinding step, in cases where an acrylic acid ester co-polymer is used as the chief component of the UV-curable adhesive, the hydroxyl groups and carboxyl groups in the adhesive react with the grinded surface of the electronic component assembly and, even if irradiated with ultraviolet light, the adhesive force does not sufficiently decline. While oxide films differ depending on the temperature and humidity at time of storage, once an oxide film is removed, it takes two or three days to regenerate. Because of this, when processing is advanced on a normal assembly line, bonding of the adhesive sheet and dicing are conducted before the oxide film regenerates, resulting in a decline in pickup.

The present invention has been developed in view of the above-described circumstances, and is based on the discovery that, by setting a specific composition to the adhesive agent that composes the adhesive layer of the adhesive sheet, even when the backgrinding step is conducted before the dicing step, the adhesive sheet and chip can be easily separated at time of pickup, enabling the pickup step to be conducted easily, leading to the completion of the present invention.

In other words, this invention relates to the below-described adhesive sheet and a production method of electronic components using the adhesive sheet. (1) An adhesive sheet comprising a base film, and a UV-curable adhesive laminated on the base film, wherein the UV-curable adhesive comprises 100 parts by mass of an acrylic acid ester co-polymer having a weight average molecular weight of at least one million, 20 to 200 parts by mass of a photopolymerizable acrylate having at least three carbon/carbon double bonds, and 0.1 to 10 parts of an isocyanate curing agent, monomers that copolymerize the acid ester co-polymer, wherein among the monomers for co-polymerization of the acrylic acid ester co-polymer, the monomers comprising a hydroxyl group or a carboxyl group or both are present in a quantity of at least 0 mass percent and at most 0.1 mass percent. (2) An adhesive sheet as described in (1), wherein the photopolymerizable acrylate comprising three carbon/carbon double bonds is a urethane acrylate. (3) An adhesive sheet as described in either (1) or (2), wherein the base film is an ionomer resin. (4) A production method of electronic components, comprising a backgrinding step of grinding the non-circuit pattern formed surface of an electronic component assembly, a bonding step of bonding the adhesive sheet recited in any of (1) to (3) to the grinded surface of the electronic component assembly following the backgrinding step, a dicing step of forming the electronic component assembly into chips of the individual electronic components following the bonding step, a UV irradiation step of irradiating the adhesive sheet with ultraviolet light following the dicing step, and a pick-up step of picking up the electronic components following the UV irradiation step.

According to the adhesive sheet of the present invention, in a production method for electronic components, the decline in the pickup success rate of chips can be controlled even when the rear surface of the electronic component assembly is grinded prior to bonding the adhesive sheet.

### MODES FOR CARRYING OUT THE INVENTION

### <Explanation of Terminology>

In the present specification, “parts” and “%” are understood to based on mass, unless otherwise indicated. In the present specification, “(meth)acryloyl group” refers collectively to acryloyl groups and methacryloyl groups. Compounds including “(meth)” such as “(meth)acrylic acid” also refer collectively to both compounds having “meth” and compounds not having “meth” in their names. The “number of functional groups of photopolymerizable acrylate” refers to the number of vinyl groups per acrylate molecule.

### <Adhesive Sheet>

The adhesive sheet comprises the base film and the UV-curable adhesive laminated on one side of the base film.

### <Base Film>

The material of the base film is a material that can withstand the dicing of the semiconductor wafer, for example, it can be a stand-alone ionomer resin formed by cross-linking polyvinyl chloride, polyethylene terephthalate, ethylene-vinyl acetate copolymer, ethylene-acrylic acid-acrylic acid ester film, ethylene-ethyl acrylate copolymer, thermoplastic olefin elastomer, polyethylene, polypropylene, polypropylene copolymer, ethylene-acrylic acid copolymer, and ethylene-(meth)acrylic acid copolymer or ethylene-(meth)acrylic acid-(meth)acrylic acid ester copolymer with a metal ion, or a mixture, copolymer, or multilayer film thereof.

Among the above-mentioned materials for the base film, ionomer resins are preferable. Among ionomer resins, those obtained by crosslinking copolymers comprising ethylene units, (meth)acrylic acid units and (meth)acrylic acid alkyl ester units with metal ions such as Na⁺, K⁺, Zn²⁺ or the like are preferable for being effective in preventing the generation of whisker-shaped shavings.

Material having a melt flow rate of 0.5 to 6.0 grams per 10 minutes (JISK7210, 210° C.) is especially preferable for the base film, material having a melting point of 80 to 98° C. is especially preferable, and material comprising Z²⁺ ions is especially preferable.

Examples of methods for forming the base film include calendering, T-die extrusion, inflation and casting, with the T-die extrusion method, which has a good thickness accuracy of the base film, being preferable.

For the purpose of preventing blocking of the base film, it is preferable to apply or knead a blocking agent and stopping agent and to administer surface texturing to the surface of the film to achieve an average roughness of less than (Ra) 5 μm. Further, it is preferable to suppress electrostatic damage by applying or kneading in an anti-static additive and to improve the adherence with the adhesive by administering anchor coat or corona discharge processing.

The thickness of the base film should preferably be at least 30 μm and more preferably, to prevent tears when the film is stretched during the pickup stage, at least 60 μm. Additionally, the thickness of the base film should be at most 300 μm and more preferably, at most, 200 μm, so as to maintain its high tensility at time of pickup.

### <UV-Curable Adhesive>

The UV-curable adhesive comprises 100 parts by mass of an acrylic acid ester co-polymer having a weight average molecular weight of at least one million, 20 to 200 parts by mass of a photopolymerizable acrylate having at least three carbon/carbon double bonds, and 0.1 to 10 parts of an isocyanate curing agent, and monomers that copolymerize the acid ester co-polymer, wherein among the monomers for co-polymerization of the acrylic acid ester co-polymer, the monomers comprising a hydroxyl group or a carboxyl group or both are added in a quantity of at least 0 mass percent and at most 0.1 mass percent.

### Acrylic Acid Ester Co-Polymer

The acrylic acid ester co-polymer having a weight average molecular weight of at least one million in the UV-curable adhesive is a polymer obtained by polymerizing alkyl (meth)acrylate and alkoxyalkyl (meth)acrylate or a combination thereof with other, additional polymerizable monomers.

Examples of alkyl (meth)acrylates and alkoxyalkyl (meth)acrylates used in polymerizing the acrylic acid ester co-polymer include butyl (meth)acrylate, 2-butyl (meth)acrylate, t-butyl (meth)acrylate, pentyl (meth)acrylate, octyl (meth)acrylate, 2-ethylhexyl (meth)acrylate, nonyl (meth)acrylate, decyl (meth)acrylate, lauryl (meth)acrylate, methyl (meth)acrylate, ethyl (meth)acrylate, isopropyl (meth)acrylate, tridecyl (meth)acrylate, myristyl (meth)acrylate, cetyl (meth)acrylate, stearyl (meth)acrylate, cyclohexyl (meth)acrylate, isobornyl (meth)acrylate, dicyclopentanyl (meth)acrylate, benzyl(meth)acrylate, methoxyethyl (meth)acrylate, ethoxyethyl (meth)acrylate, butoxymethyl (meth)acrylate, and ethoxy-n-propyl (meth)acrylate, either singly or as a mixture thereof.

Of these, methoxymethyl acrylate, ethoxymethyl acrylate, 2-methoxyethyl acrylate, 2-ethoxyethyl acrylate, 2-propoxyethyl acrylate, 2-butoxyethyl acrylate, 2-methoxypropyl acrylate, 3-methoxypropyl acrylate, 2-ethoxypropyl acrylate, 3-ethoxypropyl acrylate, 2-methoxybuytl acrylate, 3-methoxybutyl acrylate, 4-methoxybutyl acrylate, 2-ethoxybutyl acrylate, 3-ethoxybutyl acrylate, and 4-ethoxybutyl acrylate, and of these, methylacrylate, ethylacrylate, 2-butylacrylate, and 2-methoxyethyl acrylate in particular can be used to obtain a balance between oil resistance and cold resistance.

Functional group-containing monomers comprising a hydroxyl group and functional group-containing monomers comprising a carboxyl group are examples of other polymerizable monomers.

As examples of functional group-containing monomers comprising a hydroxyl group, there are, for example, 2-hydroxyethyl (meth)acrylate, 2-hydroxypropyl (meth)acrylate, 2-hydroxybutyl (meth)acrylate, and 2-hydroxyethyl vinyl ether.

As examples of functional group-containing monomers comprising a carboxyl group, there are (meth)acrylic acid, crotonic acid, maleic acid, maleic anhydride, itaconic acid, fumaric acid, acrylamide N-glycolic acid, and cinnamic acid.

Regarding the acrylic acid ester copolymer, of the monomers for polymerization of the acrylic acid ester copolymer, the monomers that comprise a hydroxyl group or a carboxyl group or both must be present in a quantity of at least 0 mass % and at most 0.1 mass %. If the amount of the monomers comprising a hydroxyl group or a carboxyl group or both is less than 0.1 mass %, the good pickup ability of chips can be maintained, even with respect to electronic component assemblies that have had their oxide films removed in the backgrinding step.

The weight average molecular weight of the acrylic acid ester copolymer must be at least one million. If the weight average molecular weight is lowered, then there is a tendency for the UV-curable adhesive to scrape upwards toward the side surface of the chip during dicing. The weight average molecular weight is the polystyrene-converted average molecular weight measured using gel permeation chromatography.

### (Photopolymerizable Acrylate Having at Least Three Carbon/Carbon Double Bonds)

The photopolymerizable acrylate having at least three carbon/carbon double bonds, when irradiated with UV light, reacts with an ultraviolet polymerization initiator to form a three-dimensional mesh structure, and through this, cures the adhesive and lowers its adhesive force.

The number of carbon/carbon double bonds is defined at least three because even after time elapses from irradiation, no increase in the adhesive force or decrease in pickup ability occurs. When there are at least three carbon/carbon double bonds, there tend to be few time-dependent changes in the three-dimensional mesh structure formed by irradiation.

The number-average molecular weight of the acrylate comprising at least three carbon/carbon double bonds is preferably less than 3000. If the number-average molecular weight of an acrylate comprising three or more unsaturated bonds is high, then compatibility with the adherend deteriorates, and during the dicing stage, there is a tendency for so-called “chip-flying”, wherein the electronic components scatter, to occur. The number-average molecular weight is the polystyrene-converted average molecular weight measured using gel permeation chromatography.

As examples of an acrylate comprising at least three carbon/carbon double bonds, there are trimethylolpropane triacrylate, pentaerythritol triacrylate, pentaerythritol tetra(meth)acrylate, dipentaerythritol hexaacrylate, dipentaerythritol monohydroxy pentaacrylate, epoxy acrylate oligomer, polyster acrylate oligomer, and urethane acrylate oligomer, and of these, urethane acrylate oligomer is preferable.

The blended amount of acrylate comprising at least three carbon/carbon double bonds should preferably be 20 to 200 parts by mass with respect to 100 parts by mass of the (meth)acrylic acid ester copolymer. If the content is too low, then after the UV irradiation, the curing of the UV-curable agent tends to be insufficient, and this tends to cause poor pickup. If the content is too high, then there is a tendency at the time of dicing for the adhesive to scrape upwards and stick to the side surface of the chips.

### Isocyanate Curing Agent

The isocyanate curing agent is used to set the initial adhesive power of the adhesive sheet prior to UV irradiation. Specifically, it is a compound comprising a plurality of isocyanate groups.

As examples of compounds comprising a plurality of isocyanate groups, there are 2,4-tolylene diisocyanate, 2,6-tolylene diisocyanate, 1,3-xylene diisocyanate, 1,4-xylene diisocyanate, diphenyl-methane-4,4′-diisocyanate, diphenyl-methane-2,4′-diisocyanate, 3-methyl diphenyl methane diisocyanate, hexamethylene diisocyanate, isophorone diisocyanate, dicyclohexylmethane-4,4′-diisocyanate, lysine isocyanate, phenylene diisocyanate, tolylene diisocyanate, diphenylmethane diisocyanate, cyclohexane diisocyanate, trimethylol propane adduct, a biuret reacted with water, or trimers comprising an isocyanurate ring, or a mixture thereof.

The amount of isocyanate curing agent added is 0.1 to 10 parts per mass with respect to 100 parts by mass of the (meth)acrylic acid ester copolymer. If the content is too low, there is a tendency for the adhesive to scrape upwards and stick to the side surface of the chip during dicing, and if the content is too high, then there is a tendency for “chip-flying” to occur during dicing.

### (Other Components)

In addition to the above-described formulation, to the extent that they do not cause any negative technical effects, tackifier resins, photoiniators, thermal polymerization inhibitors, bulking agents, antioxidants, softening agents, stabilizing agents, or coloring agents can be mixed into the UV curable adhesive. With respect to the photoiniators, while they are not limited to this, they can be added in an amount of 0.5 to 10 parts per mass with respect to the 100 parts by mass of the (meth)acrylic acid ester copolymer.

### Production Method of Adhesive Sheet

There are several methods for laminating the UV-curable adhesive layer onto the base film, including the method of applying it directly by use of a coating machine, the method of bonding the two together, or the printing method. With respect to the coating machine method, there are gravure coaters, comma coaters, bar coaters, knife coaters, or roll coaters. With respect to the method of bonding the two together, there is the method of applying an adhesive to a silicone treated exposed film and bonding it to a base film. With respect to the printing method, the adhesive sheet can be printed onto the base film using intaglio printing, relief printing, lithographic printing, flexographic printing, offset printing, or screen printing.

While the thickness of the UV-curable adhesive in the adhesive sheet is not particularly limited, a thickness of 1 to 100 μm following drying is preferable.

### Production Method for Electronic Components

The production method for electronic components includes the steps of backgrinding the non-circuit pattern formed surface of an electronic component assembly, bonding the adhesive sheet to the grinded surface of the electronic component assembly following the backgrinding step, dicing the electronic component assembly into individual electronic components in order to make chips following the bonding step, irradiating the adhesive sheet with ultraviolet light following the dicing step and picking up the electronic components following the ultraviolet irradiation step.

As examples electronic component assemblies, there are electronic component assemblies having circuit patterns formed on semiconductor wafers or on circuit board material.

The step of backgrinding and thinning the rear surface of an electronic component assembly generally thins the surface from a thickness of 625 μm to 775 μm to a thickness of 200 μm to 50 μm.

The bonding step includes bonding the adhesive-applied side of an adhesive sheet to the grinded, rear surface of an electronic component assembly and securing the electronic component assembly to the adhesive sheet.

The dicing step is a method whereby the electronic component assembly attached to the adhesive sheet is cut into individual electronic components by a rotating round blade. The electronic components are sometimes called chips, so this process is also called chipping.

The ultraviolet irradiation step involves irradiating the adhesive sheet with ultraviolet light, which causes the ultraviolet polymerization compound, which comprises a photoinitiator and unsaturated bonds, to react, forming a three-dimensional mesh structure, and through this, curing the adhesive and decreasing its adhesive force.

As examples of ultraviolet light sources, there are black lights, low-pressure mercury lamps, high-pressure mercury lamps, ultrahigh pressure mercury lamps, metal-halide lamps, or excimer lamps. The irradiation intensity of the ultraviolet light should preferably be more than 5 mJ/cm² and less than 1000 mJ/cm². If the intensity of irradiation is too weak, then there is a tendency for the curing of the adhesive to be insufficient, thus causing a decrease in the pickup ability, whereas if the intensity of irradiation is too strong, then there is a tendency for the curing to progress too much, and this causes the electronic components to fall off of the adhesive sheet prior to pickup.

The pickup step is a method involving stretching the adhesive sheet as necessary and using a needle to push the chips up from the adhesive sheet side, using a vacuum collet or vacuum tweezers to adsorb them, and picking them up.

### EXAMPLES

Examples of the present invention and comparative examples are provided below. These are used to further explain the present invention; the present invention is not limited by them.

### Adhesive Sheet

Using the below-described base films and UV-curable adhesives, various adhesive sheets were produced as examples and comparative examples.

### Base Film

The base film is an ionomer resin with Zn salts of an ethylene-methacrylic acid-methacrylic acid alkyl ester copolymer as its main component. Specifically, it is a 100 μm thick HIMILAN 1650 (registered trademark Mitsui/Du Pont Polychemicals), which is a film having a melt flow rate of 1.5 g per 10 minutes (JIS K7210, 210° C.), a melting point of 96° C., and Z²⁺ ions.

### UV-Curable Adhesive

The UV-curable adhesive is obtained by blending the following: 100 parts by mass of a (meth)acrylic acid ester copolymer, 20 to 200 parts by mass of a photopolymerizable acrylate having at least three carbon/carbon double bonds, 0.1 to 10 parts of an isocyanate curing agent, and 3 parts by mass of a photoinitiator. The thick paste in the adhesive sheet is applied to a thickness of 10 μm.

### (Meth)acrylic Acid Ester Copolymer

A: A copolymer having 30 mass % of n-butyl acrylate, 50 mass % of ethylacrylate, 20 mass % of 2-methoxyethylacrylate, Tg=−38.54° C., and a weight average molecular weight of 1.3 million.

B: A copolymer having 30 mass % of n-butyl acrylate, 50 mass % of ethylacrylate, 20 mass % of 2-methoethylacrylate, Tg=−38.54° C., and a weight average molecular weight of 900,000.

C: A copolymer having 30 mass % of n-butyl acrylate, 50 mass % of ethylacrylate, 19.95 mass % of 2-methoxyethylacrylate, 0.05 mass % of 2-hydroxyethylacrylate, Tg=−38.52° C., and a weight average molecular weight of 1.3 million. (Hydroxyl group containing monomers of 0.05 mass %)

D: A copolymer having 30 mass % of n-butyl acrylate, 50 mass % of ethylacrylate, 19.8 mass % of 2-methoxyethylacrylate, 0.2 mass % of 2-hydroxyethylacrylate, Tg=−38.47° C., and a weight average molecular weight of 1.3 million. (Hydroxyl group containing monomers of 0.2 mass %)

E: A copolymer having 30 mass % of n-butyl acrylate, 50 mass % of ethylacrylate, 19.8 mass % of 2-methoxyethylacrylate, 0.2 mass % of acrylic acid, Tg=−38.33° C., and a weight average molecular weight of 1.3 million. (Carboxyl group containing monomers of 0.2 mass %)

F: A copolymer having 30 mass % of n-butyl acrylate, 50 mass % of ethylacrylate, 19.92 mass % of 2-methoxyethylacrylate, 0.04 mass % of acrylic acid, 0.04 mass % of 2-hydroxyethylacrylate, Tg=−38.48° C., and a weight average molecular weight of 1.3 million. (Hydroxyl group containing monomers of 0.04 mass % and carboxyl group containing monomers of 0.04 mass %)

### Photopolymerizable Acrylate Having at Least Three Carbon/Carbon Double Bonds

G: A urethane acrylate compound synthesized from an isophorone diisocyanate and a pentaerythritol triacrylate (six carbon/carbon double bonds).

H: Trimethylolpropoane triacrylate (three carbon/carbon double bonds).

I: A urethane acrylate compound having an isophorone diisocyanate and 2-hydroxyethyl acrylate (two carbon/carbon double bonds).

### Isocyanate Curing Agent

A reactant of methylene diisocyanate and diol (Coronate 2067 of Nippon Polyurethane Industry Co).

### Photoinitiator

Benzyldimethylketal.

### Evaluation of Adhesive Sheet

According to the following steps (1)-(5), an electronic component assembly having a circuit pattern formed on a silicon wafer was secured using the aforementioned adhesive sheet, diced into individual electronic components (chips), the electronic components were picked up, and an evaluation of chip-flying, (chip retention) pickup ability, and adhesive residue was conducted.

### (1) Backgrinding Step

An eight inch silicon wafer having a plurality of circuit patterns formed therein was used as an electronic component assembly. The backside was grinded until it reached a thickness of 100 μm.

### (2) Bonding Step

An adhesive tape was bonded to the grinded surface of the electronic component assembly within an hour of completion of the backgrinding step.

### (3) Dicing Step

Following the bonding step there was the dicing step of dicing the electronic component assembly into individual electronic components. The amount of cutting into the adhesive sheet was set to 30 μm, and a cut that penetrated from the top surface to the bottom surface was administered. Dicing was performed to a chip size of 10 mm×10 mm. The dicing apparatus was a Disco DAD341. The dicing blade was a disco NBC-ZH2050-27HEEE. The dicing blade had an outer diameter of 55.56 mm, a blade width of 35 μm, and an inner diameter of 19.05 mm. The rotation speed of the dicing blade was 40,000 rpm, the advancement speed of the dicing blade was 80 mm/sec, the cutting water temperature was 25° C., and the cutting water quantity was 1.0 L/min.

### (4) UV Irradiation Step

Following the dicing step there was an irradiation step where the adhesive sheet was irradiated with UV light. A high pressure mercury lamp was employed as the light source, and the irradiation intensity was 150 mJ/cm².

### (5) Pickup Step

Following the irradiation step there was a pickup step. In the pickup step, the individual electronic components were pushed up with a needle pin from the side of the adhesive sheet, following which, the chips were adsorbed by a vacuum collet and then the individual chips were removed from the adhesive sheet. A Canon Machinery CAP-300 I I was used as the pickup apparatus. The needle pins had dimensions of 250 μmR. Five needle pins were used, the height of the needle pins was 0.5 mm, and the expansion of the needle pins was 8 mm.

### Chip-Flying

Chip-flying was evaluated by the chip retention rate of the electronic components on the adhesive sheet after the dicing step.

A (excellent): At least 95% of chips retained on adhesive sheet.

B (good): At least 90% and less than 95% of chips retained on adhesive sheet.

C (fail): Less than 90% of chips retained on adhesive sheet.

A passing grade was good or above.

### Pickup Ability

Within one hour of the backgrinding step, a dicing tape was applied, following which, the dicing step, irradiation step, and pickup step were carried out. The pickup ability was evaluated by the rate of chips successfully picked up during the pickup step.

A (excellent): At least 95% of chips were picked up.

B (good): At least 90% and less than 95% of chips were picked up.

C (fail): Less than 90% of chips were picked up.

A passing grade was good or above.

### Adhesive Residue

The adhesive residue was evaluated by the rate of visual confirmation of the existence of residual adhesive on the side surface of the electronic components following the pickup step.

A (excellent): Adhesive residue on less than 5% of electronic components.

B (good): Adhesive residue on at least 5% but less than 10% of electronic components.

C (fail): Adhesive residue on at least 10% of electronic components.

A passing grade was good or above.

The composition and evaluation results of the UV-curable adhesive are shown in Table 1. Throughout Table 1, “functional group containing monomers” means a monomer comprising either a hydroxyl group, or a carboxyl group, or both, and the number indicates the blending ratio (mass %) of the monomer comprising that group.

TABLE 1

| | | | | Examples | | | | Comparative Examples | | | | | | | |
|---|---|---|---|---|---|---|---|---|---|---|---|---|---|---|---|
| | | | | 1 | 2 | 3 | 4 | 1 | 2 | 3 | 4 | 5 | 6 | 7 | 8 |
| U.V- | (Meth)acryl- | Acrylic acid | A | 100 | | 100 | | 100 | 100 | 100 | 100 | | | | 100 |
| curable | ic acid | copolymer | B | | | | | | | | | 100 | | | |
| adhesive | ester | component | C | | 100 | | | | | | | | | | |
| | copolymer | (mass %) | D | | | | | | | | | | 100 | | |
| | | | E | | | | | | | | | | | 100 | |
| | | | F | | | | 100 | | | | | | | | |

| | | | | | | | | | | | | |
|---|---|---|---|---|---|---|---|---|---|---|---|---|
| Weight average molecular | 130 | 130 | 130 | 130 | 130 | 130 | 130 | 130 | 90 | 130 | 130 | 130 |
| weight (×10,000) | | | | | | | | | | | | |
| Functional group | 0 | 0.05 | 0 | 0.08 | 0 | 0 | 0 | 0 | 0 | 0.2 | 0.2 | 0 |
| containing monomer (mass %) | | | | | | | | | | | | |

| | | | | | | | | | | | | | |
|---|---|---|---|---|---|---|---|---|---|---|---|---|---|
| Photopolymerizable | G | 100 | 100 | | 100 | 15 | 220 | 100 | 100 | 100 | 100 | 100 | |
| acrylate having carbon/ | H | | | 100 | | | | | | | | | |
| carbon double bonds | I | | | | | | | | | | | | 100 |
| | Carbon/carbon | 6 | 6 | 3 | 6 | 6 | 6 | 6 | 6 | 6 | 6 | 6 | 2 |
| | double bonds | | | | | | | | | | | | |

| | | | | | | | | | | | | | |
|---|---|---|---|---|---|---|---|---|---|---|---|---|---|
| | Isocyanate curing agent (parts by mass) | 2 | 2 | 2 | 2 | 2 | 2 | 0.07 | 12 | 2 | 2 | 2 | 2 |
| Evalua- | Chip-flying | A | A | A | A | B | A | A | C | A | A | A | A |
| tion | Pickup ability | A | B | B | B | C | C | B | A | C | C | C | C |
| | Adhesive residue | A | A | A | A | A | C | C | A | C | A | A | A |

As illustrated in Table 1, an evaluation of A (excellent) for chip-flying, pickup ability, and adhesive residue was obtainable with example 1.

Example 2, with the exception of the acrylic acid ester copolymer component being C instead of A as it was for example 1, was the same as example 1, and example 3, with the exception of the photopolymerizable acrylate having carbon/carbon double bonds being H instead of G, as it was for example 1, was the same as example 1. Both example 2 and example 3 garnered evaluations of A (excellent) with respect to chip-flying and adhesive residue, and their evaluations with respect to pickup ability were within the passing range.

Example 4, with the exception of the acrylic acid ester copolymer component being C instead of A, as it was for example 1, was the same as example 1. Example 4 garnered evaluations of A (excellent) with respect to chip-flying and adhesive residue, and its evaluation with respect to pickup ability was within the passing range.

Comparative example 1 changed the blending ratio of photopolymerizable acrylate having carbon/carbon double bonds G from 100 mass % to 15 mass %. As this blending ratio was too low, the evaluation of chip-flying dropped to B (good) and the evaluation of pickup ability dropped to C (fail).

Comparative example 2 changed the blending ratio of photopolymerizable acrylate having carbon/carbon double bonds G from 100 mass % to 220 mass %. As this blending ratio was too high, the evaluations of the pickup ability and adhesive residue dropped to C (fail).

Comparative example 3 changed the blending ratio of the isocyanate curing agent from 2 parts by mass to 0.07 parts by mass. As the mixing ratio of the isocyanate curing agent was too low, the evaluation of the pickup ability dropped to B (good) and the evaluation of the adhesive residue dropped to C (fail).

Comparative example 4 changed the blending ratio of the isocyanate curing agent from 2 parts by mass to 12 parts by mass. As the blending ratio of the isocyanate curing agent was too high, the evaluation of chip-flying dropped to C (fail).

Comparative example 5 was the same as example 1, with the exception of the acrylic acid ester copolymer component being B instead of A and the weight average molecular weight being 900,000 instead of 1.3 million as they were for example 1. As the weight average molecular weight of the acrylic acid ester copolymer component was too low, the evaluations for pickup ability and adhesive residue dropped to C (fail).

Comparative example 6 was the same as example 1, with the exception of the acrylic acid ester copolymer component being D instead of A and the mass percent of the functional group containing monomer being 0.2% instead of 0% as they were for example 1. As the mass of the functional group containing monomer of the acrylic acid copolymer component was too great, the evaluation of the pickup ability dropped to C (fail).

Comparative example 7 was the same as example 1, with the exception of the acrylic acid ester copolymer component being E instead of A and the mass percent of the functional group containing monomer being 0.2% instead of 0% as they were for example 1. As the mass of the functional group containing monomer of the acrylic acid copolymer component was too great, the evaluation of the pickup ability dropped to C (fail).

Comparative example 8 was the same as example 1, with the exception of the photopolymerizable acrylate having carbon/carbon double bonds being I instead of G, as it was for example 1. As the number of functional groups of the photopolymerizable acrylate having carbon/carbon double bonds was too few, the evaluation of the pickup ability dropped to C (fail).

1. An adhesive sheet, comprising:
a base film; and
a UV-curable adhesive laminated on the base film;
wherein the UV-curable adhesive comprises 100 parts by mass of an acrylic acid ester co-polymer having a weight average molecular weight of at least one million, 20 to 200 parts by mass of a photopolymerizable acrylate having at least three carbon/carbon double bonds, and 0.1 to 10 parts of an isocyanate curing agent, monomers that copolymerize the acrylic acid ester co-polymer, wherein among the monomers for co-polymerization of the acrylic acid ester co-polymer, the monomers comprising a hydroxyl group or a carboxyl group or both are present in a quantity of at least 0 mass percent and at most 0.1 mass percent.

2. An adhesive sheet as recited in claim 1, wherein the photopolymerizable acrylate comprising three carbon/carbon double bonds is a urethane acrylate.

3. An adhesive sheet as recited in claim 1, wherein the base film is an ionomer resin.

4. A production method of electronic components, comprising:
a backgrinding step of grinding a non-circuit pattern formed surface of an electronic component assembly;
a bonding step of bonding the adhesive sheet recited in any of the claims 1 to 3 to the grinded surface of the electronic component assembly following the backgrinding step;
a dicing step of forming the electronic component assembly into chips of the individual electronic components following the bonding step;
a UV irradiation step of irradiating the adhesive sheet with ultraviolet light following the dicing step; and
a pick-up step of picking up the electronic components following the UV irradiation step.
